(19) United States
(12) Patent Application Publication
(10) Pub. No.: US 2026/0122932 A1
(43) Pub. Date: Apr. 30, 2026

(54) SEMICONDUCTOR DEVICE

(71) Applicant: Samsung Electronics Co., Ltd., Suwon-si (KR)

(72) Inventors: Keonhee Park, Suwon-si (KR); Yeonjin Lee, Suwon-si (KR); Haewook Jeong, Suwon-si (KR)

(21) Appl. No.: 19/342,545

(22) Filed: Sep. 27, 2025

(30) Foreign Application Priority Data
Oct. 25, 2024 (KR) 10-2024-0147936

(51) Int. Cl. H10D 1/68; H01L 23/00; H01L 23/48; H01L 25/16; H10B 80/00; H10D 80/20; H10D 80/30

(52) U.S. Cl. CPC H10D 1/716; H10D 1/712; H10D 1/714; H10W 90/00; H10B 80/00; H10D 80/215; H10D 80/30; H10W 20/20; H10W 72/823; H10W 90/26; H10W 90/722

(57) ABSTRACT

Provided is a semiconductor device including a buffer die configured to communicate with an external device, a memory die stack including a plurality of memory dies stacked on the buffer die and connected to the buffer die through a plurality of through silicon vias, and a capacitor arranged on an upper portion of an uppermost memory die among the plurality of memory dies, wherein the capacitor surrounds at least some surfaces of the plurality of memory dies, when viewed in a top down view.

### CROSS-REFERENCE TO RELATED APPLICATION

This application is based on and claims priority under 35 U.S.C. § 119 to Korean Patent Application No. 10-2024-0147936, filed on Oct. 25, 2024, in the Korean Intellectual Property Office, the disclosure of which is incorporated by reference herein in its entirety.

### BACKGROUND

The inventive concept relates to a semiconductor device. More particularly, the inventive concept relates to a structure of a capacitor capable of covering at least a portion of a memory device having a vertical stack structure.

Recently, there has been a trend towards increasing the capacity and speed of semiconductor memories used as memories in most electronic systems. Additionally, various attempts have been made to mount higher-capacity memories in smaller areas and drive these memories more efficiently.

Recently, to increase the integration of semiconductor memories, three-dimensional (3D) arrangement technology for stacking a plurality of memory chips has started to be applied to existing two-dimensional (2D) arrangements. To meet the demands for highly integrated and high-capacity memories, research has been conducted on structures that increase capacity based on 3D arrangement structures of the memory chips, enhance integration by reducing the size of semiconductor chips, and reduce manufacturing costs at the same time.

### SUMMARY

The inventive concept provides a structure of a semiconductor device configured to efficiently discharge heat.

According to an aspect of the inventive concept, there is provided a semiconductor device.

The semiconductor device includes a buffer die configured to communicate with an external device, a memory die stack including a plurality of memory dies stacked on the buffer die and connected to the buffer die through a plurality of through silicon vias, and a capacitor arranged on an upper portion of an uppermost memory die among the plurality of memory dies, wherein the capacitor surrounds at least some surfaces of the plurality of memory dies, when viewed in a top down view.

According to an aspect of the inventive concept, there is provided a semiconductor device.

The semiconductor device includes a memory device including a buffer die configured to communicate with an external device and a memory die stack including a plurality of memory dies stacked on the buffer die and connected to the buffer die through a plurality of through silicon vias, and a capacitor electrically connected to the memory device and covering at least a portion of the memory device, wherein the capacitor includes a first electrode, a second electrode, and a dielectric arranged between the first electrode and the second electrode.

According to an aspect of the inventive concept, there is provided a semiconductor device.

The semiconductor device includes a memory device including a buffer die configured to communicate with an external device and a memory die stack including a plurality of memory dies stacked on the buffer die and connected to the buffer die through a plurality of through silicon vias, a system on chip including a processor, an interposer substrate connecting the memory device to the system on chip, and a capacitor electrically connected to the memory device and covering at least a portion of each of the memory device and the system on chip.

### BRIEF DESCRIPTION OF THE DRAWINGS

Embodiments will be more clearly understood from the following detailed description taken in conjunction with the accompanying drawings in which:

FIG. 1 is a block diagram of a semiconductor device, according to an example embodiment;

FIG. 2 is a block diagram of a memory device of FIG. 1;

FIG. 3 is a cross-sectional view of a semiconductor device, according to an example embodiment;

FIGS. 4A and 4B each illustrate a connection structure between an uppermost memory die and a capacitor, according to an example embodiment;

FIG. 5 illustrates a semiconductor device including a memory device and a capacitor, according to an example embodiment;

FIG. 6 illustrates a semiconductor device including a memory device and a capacitor, according to an example embodiment;

FIG. 7 illustrates a semiconductor device including a memory device and a capacitor, according to an example embodiment;

FIG. 8 illustrates a semiconductor device including a memory device and a capacitor, according to an example embodiment;

FIGS. 9A and 9B illustrate semiconductor devices each including a memory device and a capacitor, according to an example embodiment;

FIGS. 10A to 10C illustrate semiconductor devices each including a memory device and a capacitor, according to an example embodiment;

FIG. 11 illustrates a semiconductor device according to an example embodiment;

FIGS. 12A to 12C illustrate semiconductor devices each including a memory device and a capacitor, according to an example embodiment;

FIGS. 13A and 13B illustrate semiconductor devices, according to an example embodiment; and

FIGS. 14A to 14G illustrate a method of manufacturing a semiconductor device, according to an example embodiment.

### DETAILED DESCRIPTION OF THE EMBODIMENTS

Hereinafter, example embodiments are described with reference to the attached drawings. Like reference characters refer to like elements throughout. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise. For example, items described as “substantially the same,” “substantially equal,” or “substantially planar,” may be exactly the same, equal, or planar, or may be the same, equal, or planar within acceptable variations that may occur, for example, due to manufacturing processes

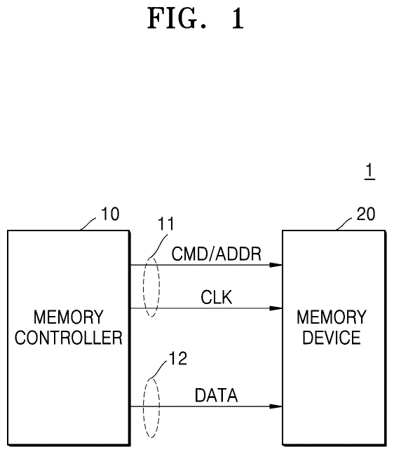

FIG. 1 is a block diagram of a semiconductor device according to an example embodiment.

Referring to FIG. 1, a semiconductor device 1 according to an embodiment may include a memory controller 10 and a memory device 20.

The memory controller 10 and the memory device 20 may each include an interface for mutual communication. The interfaces may be connected through a control bus 11 configured to transmit commands CMD, addresses ADDR, clock signals CLK, and the like, and a data bus 12 configured to transmit data DATA. The command CMD may be regarded as including the address ADDR. The memory controller 10 may provide the memory device 20 with, for example, refresh commands, commands for setting all registers of the memory device 20, and the like.

The memory controller 10 may generate a command CMD for controlling the memory device 20, and under the control by the memory controller 10, data DATA may be written to the memory device 20 or read therefrom.

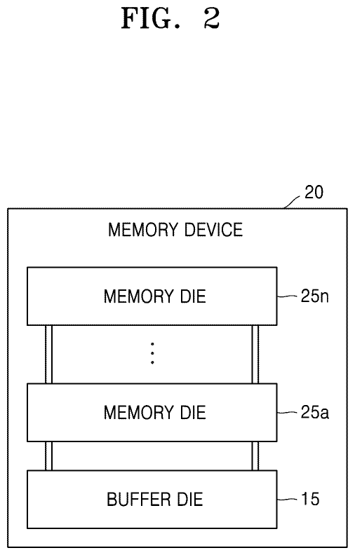

FIG. 2 is a block diagram of the memory device 20 of FIG. 1.

Referring to FIG. 2, the memory device 20 may be a stack memory device including a buffer die 15 and a plurality of memory dies 25a to 25n (where, n is a natural number of at least 2). A memory die stack may be include a plurality of memory dies 25a to 25n stacked on the buffer die. The memory device 20 may be packaged as the buffer die 15 and the plurality of memory dies 25a to 25n are stacked. The memory dies 25a to 25n may be stacked on the buffer die 15 and electrically connected thereto. The memory dies 25a to 25n may be electrically connected to the buffer die 15 through, for example, through silicon vias (TSVs).

The buffer die 15 may communicate with the memory controller 10. The memory dies 25a to 25n may each be Dynamic Random Access Memory (DRAM) such as Double Data Rate Synchronous Dynamic Random Access Memory (DDR SDRAM), Low Power Double Data Rate (LPDDR) SDRAM, Graphics Double Data Rate (GDDR) SDRAM, or Rambus Dynamic Random Access Memory (RDRAM).

According to an embodiment, a capacitor connected to the memory device 20 may be further included. As arranged to cover at least a portion of the outer surface of the memory device 20, the capacitor may improve the power performance of the memory device 20 and facilitate heat dissipation. In addition, electrodes of the capacitor may be electrically connected to the semiconductor device through a TSV of an uppermost memory die of the memory device 20 or a redistribution layer of the buffer die. Hereinafter, the connection structure between the capacitor and the memory device 20 is described in more detail with reference to the attached drawings.

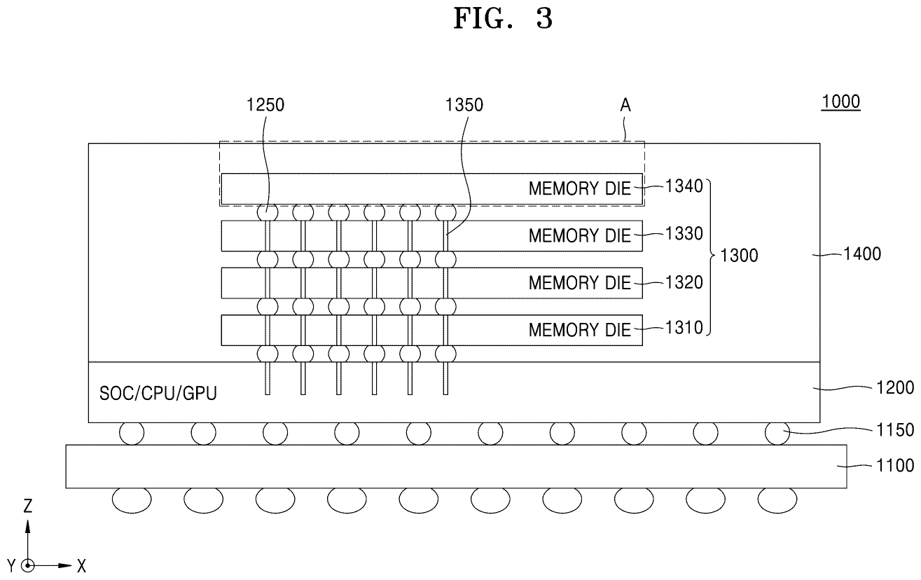

FIG. 3 is a cross-sectional view of a semiconductor device according to an example embodiment.

Referring to FIG. 3, a semiconductor device 1000 according to an embodiment may be applied to a three-dimensional (3D) chip structure. The semiconductor device 1000 may include a package substrate 1100, a system-on-chip (SoC) 1200, a memory device 1300, and a capacitor 1400. The SoC 1200 may be disposed over the package substrate 1100. The SoC 1200 may be connected to the package substrate 1100 through flip chip bumps 1150. The SoC 1200 may include a processor configured to execute various operations for applications supported by the semiconductor device 1000. For example, the SoC 1200 may include at least one of a Central Processing Unit (CPU), an Image Signal Processor (ISP), a Digital Signal Processor (DSP), a Graphics Processing Unit (GPU), a Vision Processing Unit (VPU), and a Neural Processing Unit (NPU). The SoC 1200 may include a physical layer electrically connected to a buffer die (not shown). The SoC 1200 may store data, which is required for operations, in the memory device 1300 or read the same from the memory device 1300. The SoC 1200 may include the memory controller 10 described above.

The memory device 1300 may include a plurality of memory dies 1310, 1320, 1330, and 1340 that are stacked. The memory dies 1310 to 1340 may form a High Bandwidth Memory (HBM) structure. To implement the HBM structure, TSVs 1350 may be formed in the memory dies 1310 to 1340. The TSVs 1350 may be electrically connected to micro-bumps 1250 formed between the memory dies 1310 to 1340. The memory dies 1310 to 1340 may respectively correspond to the memory dies 25a to 25n described above.

Although buffer dies or logic dies are not shown in FIG. 3, buffer dies may be arranged between the memory die 1310 and the SoC 1200. The buffer die may correspond to the buffer die 15 described above.

According to an embodiment, the capacitor 1400 may be arranged to cover an upper portion of the memory device 1300 in the Z-axis direction and side portions thereof in the X-axis direction. Although not shown in FIG. 3, the capacitor 1400 may also be arranged to cover side portions of the memory device 1300 in the Y-axis direction. The capacitor 1400 may be arranged to cover all or some portions of the memory device 1300. The capacitor 1400 may be electrically connected to the memory device 1300. According to an embodiment, the capacitor 1400 electrically connected to the memory device 1300 having the HBM structure may be included, and the capacitor 1400 may be formed to surround the memory device 1300, thus facilitating the heat discharge from the memory device 1300. In the present specification, the description that the capacitor 1400 covers the memory device 1300 may indicate that the capacitor 1400 is arranged to contact at least part of outer surfaces of the memory device 1300 to surround the memory device 1300. In example embodiments, when viewed top down, the capacitor 1400 may extend around the entire perimeter of the memory device 1300. In example embodiments, the capacitor 1400 may extend to cover the entire edge portion of the top surface of the memory device 1300.

The capacitor 1400 of the inventive concept may be a decoupling capacitor or a power capacitor that may reduce noise, but embodiments are not limited thereto. Hereinafter, the structure of the capacitor 1400 and the connection structure between the capacitor 1400 and the memory device 1300 are described in more detail.

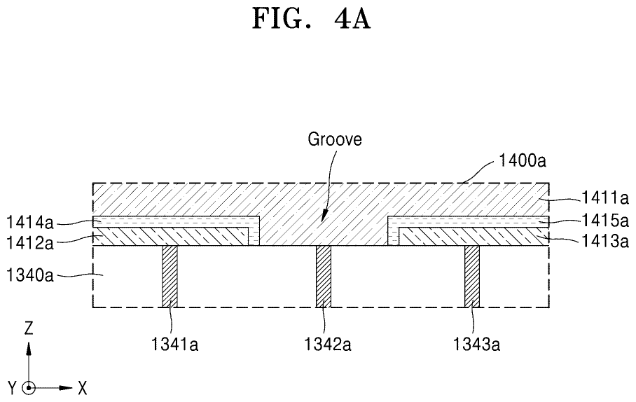

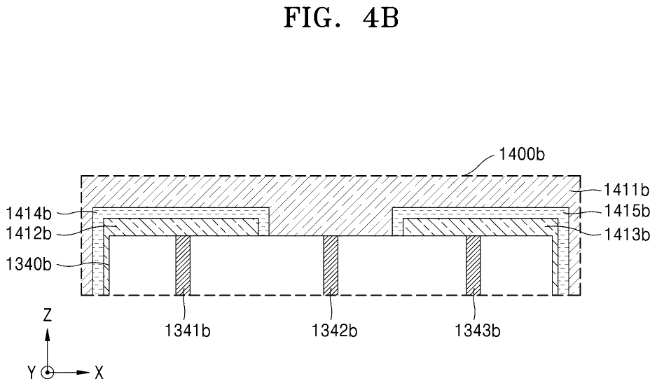

FIGS. 4A and 4B each illustrate a connection structure between an uppermost memory die and a capacitor, according to an example embodiment. According to an embodiment, FIGS. 4A and 4B are cross-sectional views showing region A of FIG. 3.

Referring to FIG. 4A, a capacitor 1400a is arranged on an upper portion of an uppermost memory die 1340a. In the present specification, the uppermost memory die 1340a may refer to a die that is the uppermost among the memory dies that are stacked to implement the HBM structure. Uppermost memory die 1340a and capacitor 1400a may correspond to memory die 1340 and capacitor 1400, respectively, of FIG. 3.

The capacitor 1400a of the inventive concept may include a first electrode 1411a, second electrodes 1412a and 1413a, and dielectrics 1414a and 1415a. Each of the first electrode 1411a, the second electrodes 1412a and 1413a, and the dielectrics 1414a and 1415a may contact an upper surface of the uppermost memory die 1340a. The second electrodes 1412a and 1413a may be separate electrodes. For example, the second electrodes 1412a and 1413a may be discrete electrodes. The first electrode 1411a and the second electrodes 1412a and 1413a may include conductive materials. According to an embodiment, the first electrode 1411a and the second electrodes 1412a and 1413a may include heat slug materials. According to an embodiment, the first electrode 1411a and the second electrodes 1412a and 1413a may include metal materials that may be effective for heat dissipation. According to an embodiment, the first electrode 1411a and the second electrodes 1412a and 1413a may include metal materials such as copper (Cu), aluminum (Al), and molybdenum (Mo) or materials such as silicon germanium (SiGe) and graphite. The dielectrics 1414a and 1415a may include dielectric materials. According to an embodiment, the dielectrics 1414a and 1415a may include materials included in a DRAM capacitor. According to an embodiment, the dielectrics 1414a and 1415a may include ferrous components. According to an embodiment, the capacitor 1400a may be formed as the second electrodes 1412a and 1413a, the dielectrics 1414a and 1415a, and the first electrode 1411a are sequentially stacked. According to an embodiment, the number of first electrodes 1411a may be different from that of second electrodes 1412a and 1413a. FIG. 4A illustrates an example in which there are a single first electrode 1411a and two second electrodes 1412a and 1413a; however, the number of second electrodes 1412a and 1413a is not limited thereto and may be at least three.

According to an embodiment, the cross-sectional areas of the second electrodes 1412a and 1413a may be less than that of the first electrode 1411a. In the present specification, the term “cross-sectional area” may refer to an area of each electrode or dielectric when viewed from the top in the Z-axis direction. According to an embodiment, the cross-sectional areas of the dielectrics 1414a and 1415a may be greater than those of the second electrodes 1412a and 1413a and less than that of the first electrode 1411a. For example, the dielectrics 1414a and 1415a may be formed by surrounding portions of the second electrodes 1412a and 1413a, and the first electrode 1411a may be formed by surrounding portions of the dielectrics 1414a and 1415a. In example embodiments, the dielectrics 1414a and 1415a may contact upper and side surfaces of the second electrodes 1412a and 1413a, and the first electrode 1411a may contact upper and side surfaces of the dielectrics 1414a and 1415a. According to an embodiment, because the first electrode 1411a is formed to fully surround the upper portion of the uppermost memory die 1340a, the cross-sectional area of the first electrode 1411a may be the same as or greater than that of the uppermost memory die 1340a. In a 2.5D structure described below, a first electrode of a capacitor may be formed to fully surround both a memory device and a SoC, and even in this case, the cross-sectional area of the first electrode may be the same as or greater than that of an uppermost memory die.

Referring to FIG. 4A, the first electrode 1411a may be T-shaped. The first electrode 1411a may include a groove (or groove extension). The groove in the first electrode 1411a may refer to a portion with a different height in the Z-axis direction among the entire portion of the first electrode 1411a. The groove in the first electrode 1411a may extend between second electrode 1412a and second electrode 1413a and between dielectric 1414a and dielectric 1415a. For example, the groove in the first electrode 1411a may overlap the second electrodes 1412a and 1413a in the X-axis direction and overlap the dielectrics 1414a and 1415a in the X-axis direction. According to an embodiment, a lower portion of the groove may contact the uppermost memory die 1340a.

The uppermost memory die 1340a may include a first TSV 1341a, a second TSV 1342a, and a third TSV 1343a. According to an embodiment, the first TSV 1341a, the second TSV 1342a, and the third TSV 1343a included in the uppermost memory die 1340a may be connected to the capacitor 1400a. According to an embodiment, the first TSV 1341a and the third TSV 1343a may be respectively connected to the second electrodes 1412a and 1413a of the capacitor 1400a, and the second TSV 1342a may be connected to the first electrode 1411a of the capacitor 1400a. FIG. 4A illustrates that the uppermost memory die 1340a includes three TSVs, but embodiments are not limited thereto. The number of TSVs may be N, where N is a natural number of at least two.

Referring to FIG. 4A, the capacitor 1400a may have a structure in which the second electrodes 1412a and 1413a, the dielectrics 1414a and 1415a, and the first electrode 1411a are sequentially stacked, and the capacitor 1400a and the uppermost memory die 1340a may contact both the first electrode 1411a and the second electrodes 1412a and 1413a. The uppermost memory die 1340a may include the first TSV 1341a, the second TSV 1342a, and the third TSV 1343a that may be respectively connected to the first electrode 1411a and the second electrodes 1412a and 1413a.

FIG. 4B illustrates an uppermost memory die 1340b and a capacitor 1400b on an upper portion of the uppermost memory die 1340b. Uppermost memory die 1340b and capacitor 1400b may correspond to memory die 1340 and capacitor 1400, respectively, of FIG. 3.

According to an embodiment, the uppermost memory die 1340b may include a first TSV 1341b, a second TSV 1342b, and a third TSV 1343b. Because the structure of the uppermost memory die 1340b that includes the first TSV 1341b, the second TSV 1342b, and the third TSV 1343b corresponds to that of the uppermost memory die 1340a of FIG. 4A, repeated descriptions are not repeated.

Referring to FIG. 4B, the capacitor 1400b may include a first electrode 1411b, second electrodes 1412b and 1413b, and dielectrics 1414b and 1415b. Because part of the structure of the capacitor 1400b corresponds to the structure of the capacitor 1400a of FIG. 4A, repeated descriptions are not repeated.

The second electrodes 1412b and 1413b of the capacitor 1400b of FIG. 4B may contact both an upper surface and side surfaces of the uppermost memory die 1340b. The second electrodes 1412b and 1413b may have greater heights than that of the uppermost memory die 1340b in the Z-axis direction, and the second electrodes 1412b and 1413b may be symmetrical to each other with respect to the center of the uppermost memory die 1340b. According to an embodiment, two second electrodes 1412b and 1413b may be provided.

The dielectrics 1414b and 1415b of the capacitor 1400b of FIG. 4B may be arranged on upper portions of the second electrodes 1412b and 1413b, respectively. The dielectrics 1414b and 1415b of the capacitor 1400b of FIG. 4B may contact upper and side surfaces of the second electrodes 1412b and 1413b, respectively. The cross-sectional area of each of the second electrodes 1412b and 1413b may be less than that of the first electrode 1411b. According to an embodiment, the cross-sectional areas of the dielectrics 1414b and 1415b may be greater than those of the second electrodes 1412b and 1413b, but less than that of the first electrode 1411b. The dielectrics 1414b and 1415b may be formed to fully surround the second electrodes 1412b and 1413b, and the first electrode 1411b may be formed to completely surround the dielectrics 1414b and 1415b. The first electrode 1411b may contact upper and side surfaces of the dielectrics 1414b and 1415b.

Referring to FIG. 4B, the capacitor 1400b may have a structure in which the second electrodes 1412b and 1413b, the dielectrics 1414b and 1415b, and the first electrode 1411b are sequentially stacked, and the capacitor 1400b and the uppermost memory die 1340b may contact both the first electrode 1411b and the second electrodes 1412b and 1413b. The uppermost memory die 1340b may include the first TSV 1341b, the second TSV 1342b, and the third TSV 1343b that may be respectively connected to the first electrode 1411b and the second electrodes 1412b and 1413b. In addition, the second electrodes 1412b and 1413b may contact both an upper surface and side surfaces of the uppermost memory die 1340b.

Referring to FIGS. 4A and 4B, the capacitors 1400a and 1400b are provided to surround the upper surfaces of the uppermost memory dies 1340a and 1340b, and heat generated by the memory devices may be easily discharged because of the materials of the first electrodes 1411a and 1411b of the capacitors 1400a and 1400b which facilitate heat dissipation, and additional connection of the capacitors 1400a and 1400b to the memory devices may enable power reinforcement and noise reduction.

Hereinafter, a structure of a semiconductor device, to which the embodiments of FIGS. 4A and 4B are applied, and modified embodiments of the structure are described in more detail.

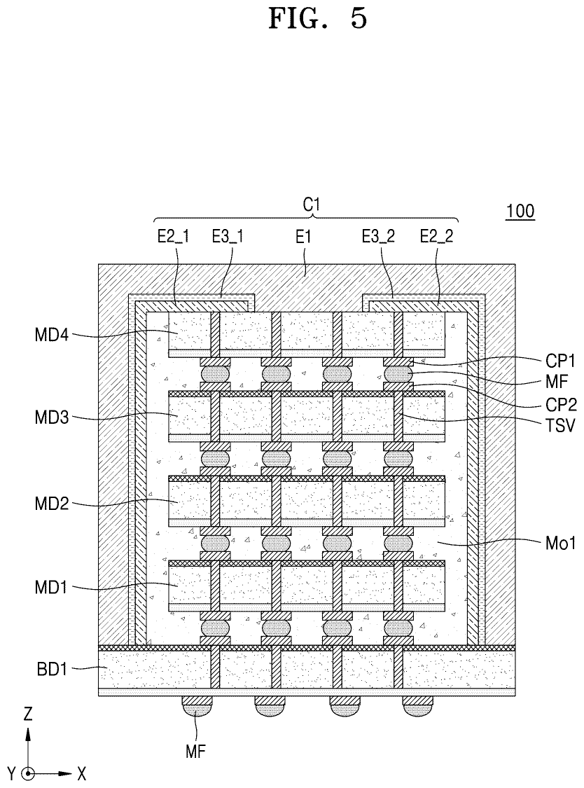

FIG. 5 illustrates a semiconductor device including a memory device and a capacitor, according to an example embodiment.

FIG. 5 shows a semiconductor device 100 including a buffer die BD1, a plurality of memory dies MD1 to MD4, and a capacitor C1. The semiconductor device 100 of FIG. 5 may correspond to the semiconductor device 1000 of FIG. 3; however, for convenience of explanation, a SoC and a package substrate are omitted, and structures corresponding to the memory device 1300 and the capacitor 1400 of FIG. 3 are only shown. For example, the plurality of memory dies MD1 to MD4 corresponds to the memory dies 1310 to 1340, and the capacitor C1 corresponds to the capacitor 1400.

The buffer die BD1 and the memory dies MD1 to MD4 may be vertically stacked and spaced apart vertically from each other at regular intervals. According to an embodiment, each of the memory dies MD1 to MD4 may have the same thickness. Referring to FIG. 5, the memory dies MD1 to MD4 may each include TSVs. FIG. 5 illustrates that each of the memory dies MD1 to MD4 includes four TSVs, but the number of TSVs included in the memory dies MD1 to MD4 is not limited to that illustrated. In the present specification, the example in which four memory dies MD1 to MD4 are included is provided, but embodiments are not limited thereto. The number of memory dies included in the semiconductor device may vary.

Referring to FIG. 5, the TSVs may be electrically connected to each other through micro-bumps MF and connection pads CP1 and CP2. Referring to FIG. 5, the semiconductor device 100 of FIG. 5 includes a first molding layer Mo1 that surrounds the memory dies MD1 to MD4 in the X-axis direction and the Y-axis direction. The first molding layer Mo1 may include, for example, an Epoxy Mold Compound (EMC). The first molding layer Mo1 may be formed to have the same height as the height at which the uppermost memory die MD4 is positioned. For example, upper surfaces of the first molding layer Mo1 and the uppermost memory die MD4 may be coplanar, leaving the upper surfaces of the uppermost memory die MD4 exposed.

According to an embodiment, the capacitor C1 may include a first electrode E1, second electrodes E2_1 and E2_2, and dielectrics E3_1 and E3_2. Referring to FIG. 5, a single first electrode E1 may be provided, and the second electrodes E2_1 and E2_2 and the dielectrics E3_1 and E3_2 may each be provided as two. For example, the second electrodes E2_1 and E2_2 and the dielectrics E3_1 and E3_2 may be provided in pairs. According to an embodiment, the capacitor C1 may be formed to cover both the uppermost memory die MD4 and the first molding layer Mo1 contacting the uppermost memory die MD4. The first electrode E1 of the capacitor C1 may contact the uppermost memory die MD4 and the buffer die BD1. The second electrodes E2_1 and E2_2 of the capacitor C1 may contact the uppermost memory die MD4 and the buffer die BD1.

The dielectrics E3_1 and E3_2 of the capacitor C1 may contact the uppermost memory die MD4 and the buffer die BD1. According to an embodiment, the memory device may be electrically connected to each of the first electrode E1 and the second electrodes E2_1 and E2_2 through the TSVs included in the uppermost memory die MD4. For example, each of the first electrode E1 and the second electrodes E2_1 and E2_2 may contact the TSVs included in the uppermost memory die MD4. According to an embodiment, the thickness of the first electrode E1 and the thicknesses of the second electrodes E2_1 and E2_2 may be greater than those of the dielectrics E3_1 and E3_2. According to an embodiment, the thickness of the first electrode E1 may be greater than those of the dielectrics E3_1 and E3_2, and the thicknesses of the second electrodes E2_1 and E2_2 may be greater than those of the dielectrics E3_1 and E3_2. According to an embodiment, the structure of the capacitor C1 of FIG. 5 may correspond to that of the capacitor 1400b described above with reference to FIG. 4B, except that a first molding layer Mo1 is provided between the side surfaces of the memory dies MD1 to MD4 and the capacitor C1. For example, when viewed top down, the capacitor C1 of FIG. 5 may extend entirely around the perimeter of the sides of the memory dies MD1 to MD4 in the X-axis direction and the Y-axis direction.

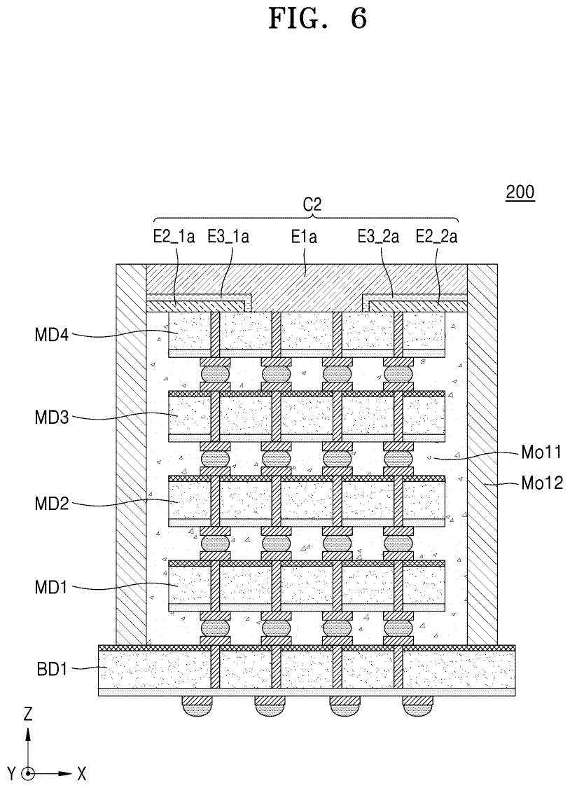

FIG. 6 illustrates a semiconductor device including a memory device and a capacitor, according to an example embodiment.

In describing a structure of a semiconductor device 200 of FIG. 6, descriptions that are substantially the same as those provided with reference to FIG. 5 are not repeated. FIG. 6 shows a semiconductor device 200 that includes a buffer die BD1, a plurality of memory dies MD1 to MD4, and a capacitor C2. The semiconductor device 200 may include a first molding layer Mo11 and a second molding layer Mo12. According to an embodiment, the first molding layer Mo11 and the second molding layer Mo12 may each include an EMC. The first molding layer Mo11 may directly contact the second molding layer Mo12. According to an embodiment, the outer side surface of the first molding layer Mo11 may contact the inner side surface of the second molding layer Mo12. According to an embodiment, the second molding layer Mo12 may physically protect the first molding layer Mo11 by surrounding the outer surface of the first molding layer Mo11. Upper surfaces of the first molding layer Mo11 and the uppermost memory die MD4 may be coplanar, leaving the upper surfaces of the uppermost memory die MD4 exposed. In example embodiments, the upper surface of the first molding layer Mo11 may be at a lower vertical level than an upper surface of the second molding layer Mo12. According to an embodiment, the first molding layer Mo11 and the second molding layer Mo12 may include homogeneous or heterogeneous materials.

In another embodiment, the first molding layer Mo11 may include at least one of silicon (Si)-based materials, thermosetting materials, thermoplastic materials, and UV-treated materials. The second molding layer Mo12 may include at least one of epoxy-based materials, thermosetting materials, thermoplastic materials, and UV-treated materials.

Referring to FIG. 6, the capacitor C2 may include a first electrode Ela, second electrodes E2_1a and E2_2a, and dielectrics E3_1a and E3_2a. The capacitor C2 of FIG. 6 differs from the capacitor C1 of FIG. 5 in that the capacitor C2 of FIG. 6 is arranged to cover only the upper surface of the uppermost memory die MD4 and is not arranged to cover the side surfaces of the first molding layer Mo11 that correspond to the side portions of the uppermost memory die MD4. For example, the second molding layer Mo12 may contact side surfaces of the first electrode Ela, the second electrodes E2_1a and E2_2a, and the dielectrics E3_1a and E3_2a. In other words, the capacitor C2 of FIG. 6 is arranged on an upper portion of the uppermost memory die MD4, and the side surfaces of the memory dies MD1 to MD4 may be covered by the first molding layer Mo11 and the second molding layer Mo12. According to an embodiment, the structure of the capacitor C2 of FIG. 6 may correspond to that of the capacitor 1400a described above with reference to FIG. 4A.

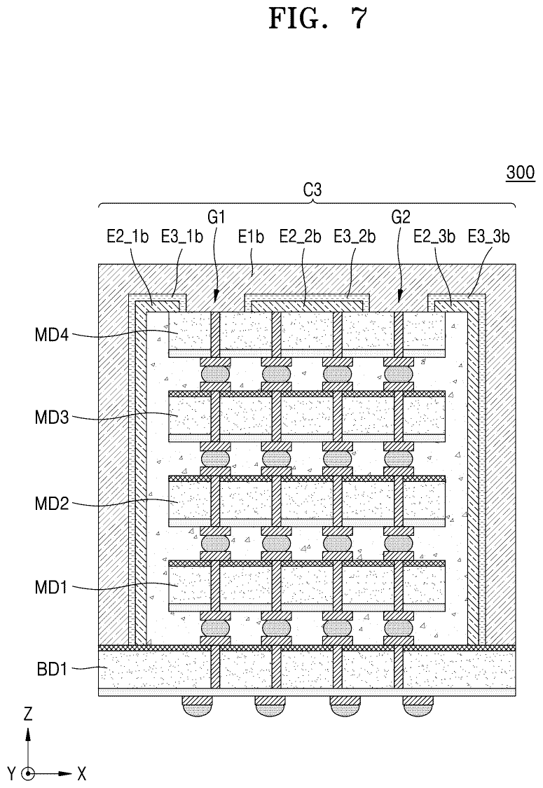

FIG. 7 illustrates a semiconductor device including a memory device and a capacitor, according to an example embodiment.

In describing a structure of a semiconductor device 300 of FIG. 7, descriptions that are substantially the same as those provided with reference to FIG. 5 are not repeated. FIG. 7 shows the semiconductor device 300 that includes a buffer die BD1, a plurality of memory dies MD1 to MD4, and a capacitor C3. According to an embodiment, the capacitor C3 may include a first electrode E1b, second electrodes E2_1b, E2_2b, and E2_3b, and dielectrics E3_1b, E3_2b, and E3_3b. According to an embodiment, each of the dielectrics E3_1b, E3_2b, and E3_3b may be arranged between the first electrode E1b and its corresponding one of the second electrodes E2_1b, E2_2b, and E2_3b.

FIG. 7 shows one first electrode E1b, three dielectrics E3_1b, E3_2b, and E3_3b, and three second electrodes E2_1b, E2_2b, and E2_3b. According to an embodiment, the first electrode E1b may include two grooves G1 and G2. Accordingly, the first electrode E1b may have two surfaces contacting the uppermost memory die MD4. In addition, due to the structure of the first electrode E1b including two grooves G1 and G2, three second electrodes E2_1b, E2_2b, and E2_3b and three dielectrics E3_1b, E3_2b, and E3_3b respectively corresponding thereto may be included. According to an embodiment, when a single first electrode of the capacitor includes M grooves, the number of second electrodes and dielectrics may each be M+1. Here, M may be a natural number of at least one.

As shown in the embodiment of FIG. 7, the structure of the first electrode E1b including a plurality of grooves may be disclosed. According to an embodiment, the first electrode E1b may be electrically connected to the TSVs of the uppermost memory die MD4 through the grooves G1 and G2 formed in the first electrode E1b. For example, each of grooves G1 and G2 of the first electrode E1b may be connected one TSV of the uppermost memory die MD4.

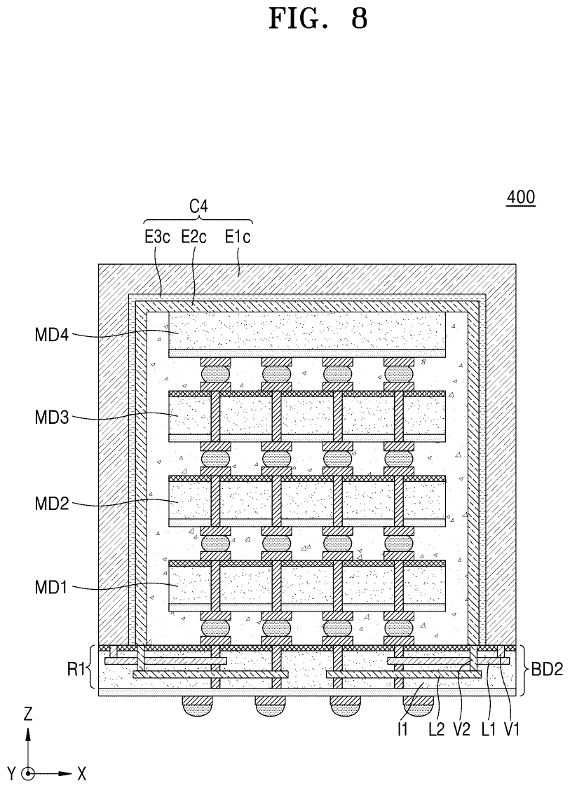

FIG. 8 illustrates a semiconductor device including a memory device and a capacitor, according to an example embodiment.

In describing a structure of a semiconductor device 400 of FIG. 8, descriptions that are substantially the same as those provided with reference to FIG. 5 are not repeated.

FIG. 8 shows the semiconductor device 400 that includes a buffer die BD2, a plurality of memory dies MD1 to MD4, and a capacitor C4. According to an embodiment, the structure of the capacitor C4 may be different from those of the capacitors C1 to C3 described above. The capacitor C4 may include a first electrode E1c, a second electrode E2c, and a dielectric E3c. The capacitor C4 may include one first electrode E1c, one second electrode E2c, and one dielectric E3c. The first electrode E1c of the capacitor C4 may not include a groove.

Referring to FIG. 8, an upper surface and side surfaces of the uppermost memory die MD4 may not contact the first electrode E1c. The second electrode E2c may contact an upper surface of the uppermost memory die MD4. In example embodiments, the second electrode E2c may contact an entire upper surface of the uppermost memory die MD4. For example, the second electrode E2c may be formed between the upper surface of the uppermost memory die MD4 and the first electrode E1c and a dielectric E3c. According to an embodiment, the uppermost memory die MD4 may not include TSVs.

According to an embodiment, the buffer die BD2 may include a re-distribution layer (RDL) R1. The RDL R1 may include at least one redistribution insulating layer I1 and a plurality of redistribution patterns L1, L2, V1, and V2. The redistribution patterns L1, L2, V1, and V2 may include a first redistribution line pattern L1, a second redistribution line pattern L2, a first redistribution via V1, and a second redistribution via V2. According to an embodiment, the first electrode E1c may be electrically connected to the memory die MD1 through the first redistribution line pattern L1 and the first redistribution via V1 included in the RDL R1. According to an embodiment, the second electrode E2c may be electrically connected to the memory die MD1 through the second redistribution line pattern L2 and the second redistribution via V2 included in the RDL R1. The capacitor C4 of FIG. 8 may be electrically connected to the memory die MD1 through the RDL R1 included in the buffer die BD2, rather than through the uppermost memory die MD4. For example, the capacitor C4 of FIG. 8 may contact an upper surface of the buffer die BD2.

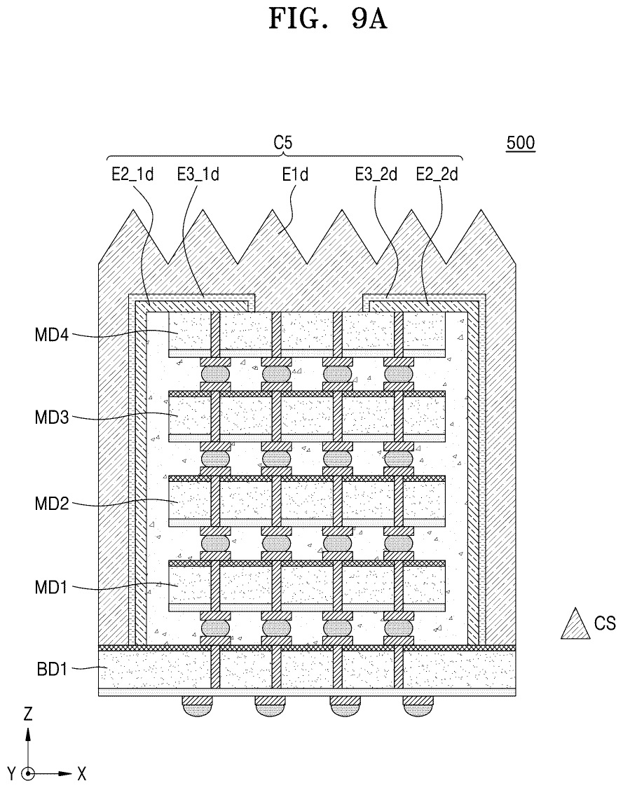

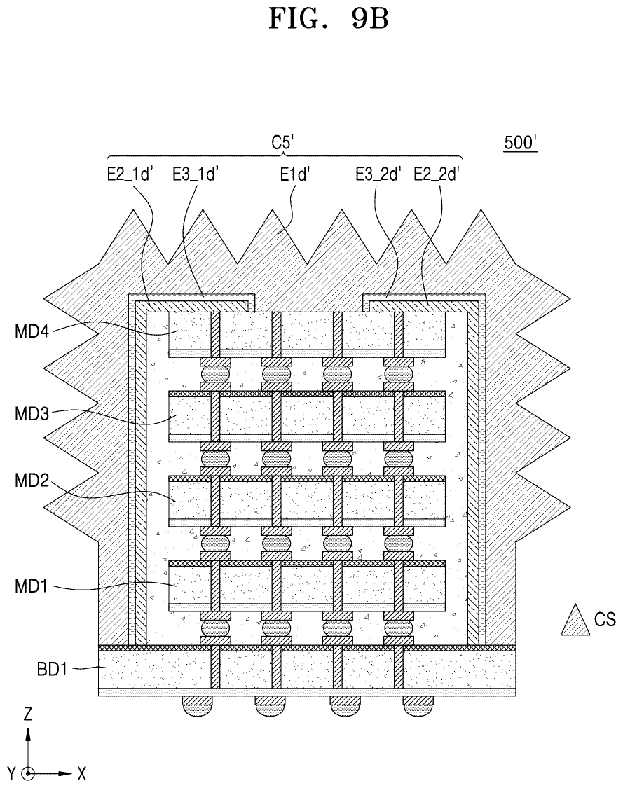

FIGS. 9A and 9B illustrate semiconductor devices each including a memory device and a capacitor, according to an example embodiment.

In describing structures of semiconductor devices 500 and 500′ of FIGS. 9A and 9B, descriptions that are substantially the same as those provided with reference to FIG. 5 are not repeated. FIG. 9A shows the semiconductor device 500 including a buffer die BD1, a plurality of memory dies MD1 to MD4, and a capacitor C5.

The capacitor C5 may include a first electrode E1d, second electrodes E2_1d and E2_2d, and dielectrics E3_1d and E3_2d. In example embodiments, the first electrode E1d, the second electrodes E2_1d and E2_2d, and the dielectrics E3_1d and E3_2d of FIG. 9A may correspond to the first electrode E1, the second electrodes E2_1 and E2_2, and the dielectrics E3_1 and E3_2 of FIG. 5, respectively. The difference between the capacitor C5 of FIG. 9A and the capacitor C1 of FIG. 5 lies in that the upper surface of the first electrode E1d of the capacitor C5 may further include a protrusion structure CS, compared to the upper surface of the first electrode E1 of the capacitor C1 of FIG. 5. In the present specification, the term “protrusion structure CS” may refer to a structure including multiple protrusions that extend to increase the area of a flat surface. In example embodiments, the protrusions of the protrusion structure CS may increase the surface by 50% or more. For example, when the protrusions of the protrusion structure CS include a series of connected equilateral triangles, the surface area may be doubled. In some embodiments, the protrusions of the protrusion structure CS may vertically overlap a region in which the first electrode E1d contacts an upper surface of the uppermost memory die MD4. As the upper surface of the first electrode E1d of the capacitor C5 includes the protrusion structure CS, the cross-sectional area of the first electrode E1d may be increased compared to that of the capacitor C1 of FIG. 5, and thus, heat may be additionally discharged. In the present specification, the protrusion structure CS is illustrated and described as being triangle-shaped; however, the shape of the protrusion structure CS is not limited thereto. The protrusion structure CS may be provided in various forms that may increase the cross-sectional area of the capacitor C5.

FIG. 9B shows the semiconductor device 500′ including a buffer die BD1, a plurality of memory dies MD1 to MD4, and a capacitor C5′. The capacitor C5′ may include a first electrode E1d′, second electrodes E2_1d′ and E2_2d′, and dielectrics E3_1d′ and E3_2d′. In example embodiments, the first electrode E1d′, the second electrodes E2_1d′ and E2_2d′, and the dielectrics E3_1d′ and E3_2d′ of FIG. 9B may correspond to the first electrode E1, the second electrodes E2_1 and E2_2, and the dielectrics E3_1 and E3_2 of FIG. 5, respectively. According to an embodiment, the upper surface of the first electrode E1d′ of the capacitor C5′ of FIG. 9B may include a protrusion structure CS. Compared to the capacitor C5 of FIG. 9A, the capacitor C5′ of FIG. 9B may include the protrusion structure CS not only on the upper surface of the first electrode E1d′ but also on the side surfaces thereof. As described, by increasing the area where the protrusion structure CS is arranged, the cross-sectional area of the capacitor C5′ may be increased, and heat dissipation efficiency may be improved.

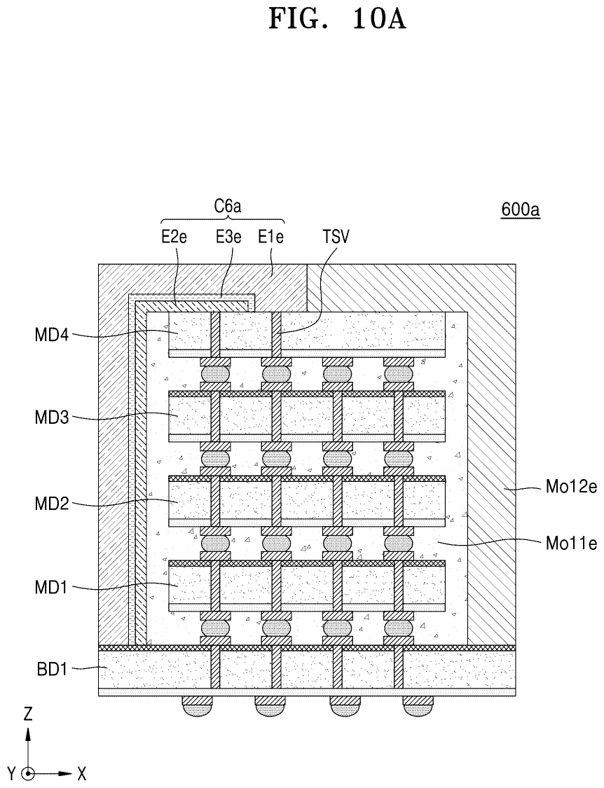

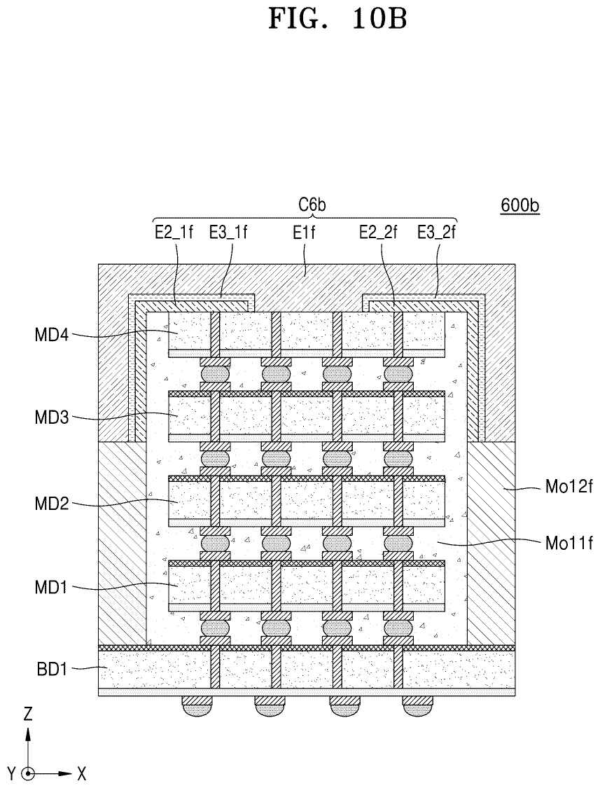

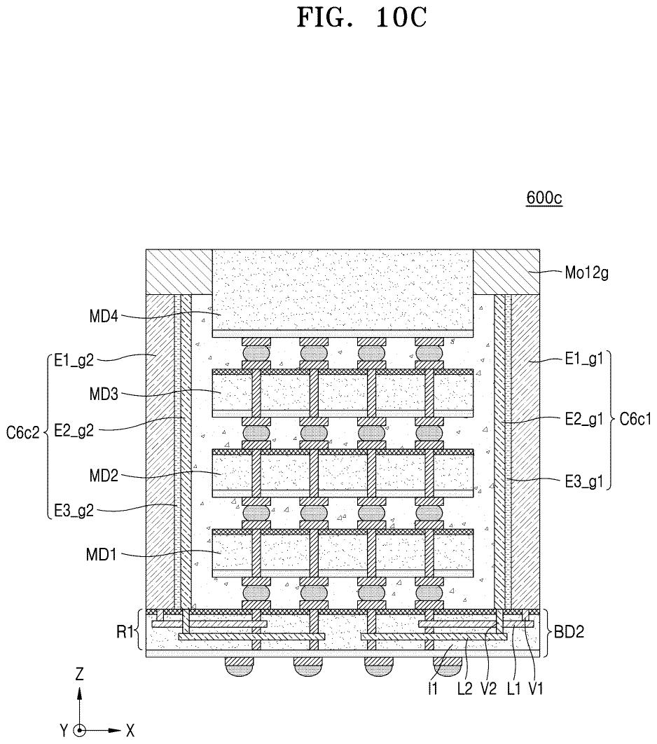

FIGS. 10A to 10C illustrate semiconductor devices each including a memory device and a capacitor, according to an example embodiment.

In describing FIGS. 10A to 10C, descriptions of structures that are substantially the same as those in the previous drawings are not repeated.

Referring to FIG. 10A, a semiconductor device 600a may include a buffer die BD1, a plurality of memory dies MD1 to MD4, and a capacitor C6a. According to an embodiment, the semiconductor device 600a may further include a first molding layer Mo11e and a second molding layer Mo12e. According to an embodiment, the capacitor C6a may include a first electrode Ele, a second electrode E2e, and a dielectric E3e. The capacitor C6a of FIG. 10A may be arranged to cover a portion of the upper surface of the uppermost memory die MD4. Referring to FIG. 10A, with respect to the center of the upper surface of the uppermost memory die MD4, the capacitor C6a may be arranged to cover the left side (e.g., a first side) of the uppermost memory die MD4, while the second molding layer Mo12e may be arranged on the right side (e.g., a second side) of the uppermost memory die MD4. Because the capacitor C6a covers the left side of the uppermost memory die MD4, TSVs, which are formed in the uppermost memory die MD4 and connected to the capacitor C6a, may be formed only in the areas contacting the first electrode Ele and the second electrode E2e of the capacitor C6a and may not be formed in the areas contacting the second molding layer Mo12e.

Referring to FIG. 10B, a semiconductor device 600b may include a buffer die BD1, a plurality of memory dies MD1 to MD4, and a capacitor C6b. According to an embodiment, the semiconductor device 600b may further include a first molding layer Mo11f and a second molding layer Mo12f. The capacitor C6b may include a first electrode Elf, second electrodes E2_1f and E2_2f, and dielectrics E3_1f and E3_2f. The capacitor C6b according to an embodiment may entirely cover the upper surface of the uppermost memory die MD4 and cover some surfaces of the first molding layer Mo11f covering the memory dies MD1 to MD4. The remaining surfaces of the first molding layer Mo11f, which is not covered by the capacitor C6b, may be covered by the second molding layer Mo12f. Because the capacitor C6b entirely covers the upper surface of the uppermost memory die MD4, the TSVs of the uppermost memory die MD4, which are configured to be connected to the capacitor C6b, may be formed within the range where the TSVs are connected to the first electrode Elf and the second electrodes E2_1f and E2_2f.

Referring to FIG. 10C, a semiconductor device 600c may include a buffer die BD2, a plurality of memory dies MD1 to MD4, a first capacitor C6ci, and a second capacitor C6c2. According to an embodiment, the thickness of the uppermost memory die MD4 in the Z-axis direction may be greater than those of the other memory dies MD1 to MD3 in the Z-axis direction.

According to an embodiment, a capacitor may not be arranged on the upper portion of the uppermost memory die MD4. Referring to the semiconductor device 600c of FIG. 10C, a second molding layer Mo12g may be arranged on the side surfaces of the uppermost memory die MD4, and the first capacitor C6cl and the second capacitor C6c2 may be respectively formed to contact side surfaces of the second molding layer Mo12g. The first capacitor C6cl may include a first electrode E1_g1, a second electrode E2_g1, and a dielectric E3_g1, and the second capacitor C6c2 may include a first electrode E1_g2, a second electrode E2_g2, and a dielectric E3_g2. The first capacitor C6c1 and the second capacitor C6c2 may not contact the uppermost memory die MD4 and may be electrically connected to memory dies MD1 to MD4 through the first redistribution via V1, the second redistribution via V2, the first redistribution line pattern L1, and the second redistribution line pattern L2 of the RDL R1 formed in the buffer die BD2.

Referring to FIGS. 10A to 10C, the capacitors may be formed to cover only a portion of the memory device, unlike the embodiments described above. When the capacitors are formed to cover only part of the memory devices, the TSVs of the uppermost memory die may be connected to correspond to the areas where the capacitors are formed, or the RDL may be connected to the buffer die.

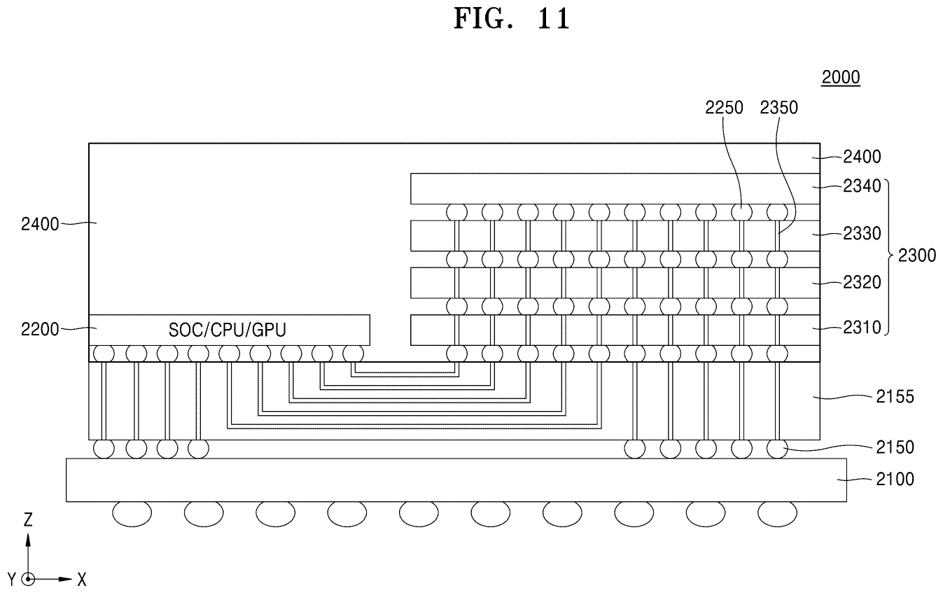

FIG. 11 shows a semiconductor device according to an example embodiment.

Referring to FIG. 11, a semiconductor device 2000 according to an embodiment may be applied to a 2.5D chip structure. The semiconductor device 2000 may include a package substrate 2100, an interposer 2155 (or an interposer substrate), a SoC 2200, and a memory device 2300 including memory dies 2310, 2320, 2330, and 2340. Because the package substrate 2100, the SoC 2200, micro-bumps 2250, the memory device 2300 including memory dies 2310, 2320, 2330, and 2340, and TSVs 2350 of FIG. 11 correspond to the package substrate 1100, the SoC 1200, the micro-bumps 1250, the memory device 1300 including memory dies 1310, 1320, 1330, and 1340, and the TSVs 1350 of FIG. 3, respectively, repeated descriptions are omitted.

The interposer 2155 may be disposed over the package substrate 2100. The interposer 2155 may be connected to the package substrate 2100 through flip chip bumps 2150. The SoC 2200 and the memory device 2300 may be disposed over the interposer 2155. The memory device 2300 may be connected to the SoC 2200 through the wiring of the interposer 2155. The memory device 2300 and the SoC 2200 may be connected to the interposer 2155 through the micro-bumps 2250.

FIG. 11 does not illustrate a buffer die or a logic die, but a buffer die may be arranged between the memory device 2300 and the interposer 2155. The buffer die may correspond to the buffer die 15 described above.

According to an embodiment, a capacitor 2400 may be arranged to cover upper portions of the memory device 2300 and the SoC 2200 in the Z-axis direction and side portions of the memory device 2300 and the SoC 2200 in the X-axis direction. Although not shown in FIG. 11, the capacitor 2400 may also be arranged to cover side portions of the memory device 2300 and the SoC 2200 in the Y-axis direction. The capacitor 2400 may be arranged to fully cover the memory device 2300 and the SoC 2200. The capacitor 2400 may be electrically connected to the memory device 2300. According to an embodiment, the capacitor 2400 configured to be electrically connected to the memory device 2300 having an HBM structure may be included, and the capacitor 2400 has a structure that surrounds the memory device 2300 and the SoC 2200, thereby improving the heat dissipation of the memory device 2300.

Hereinafter, the connection structure between the capacitor 2400, the memory device 2300, and the SoC 2200 is described in more detail.

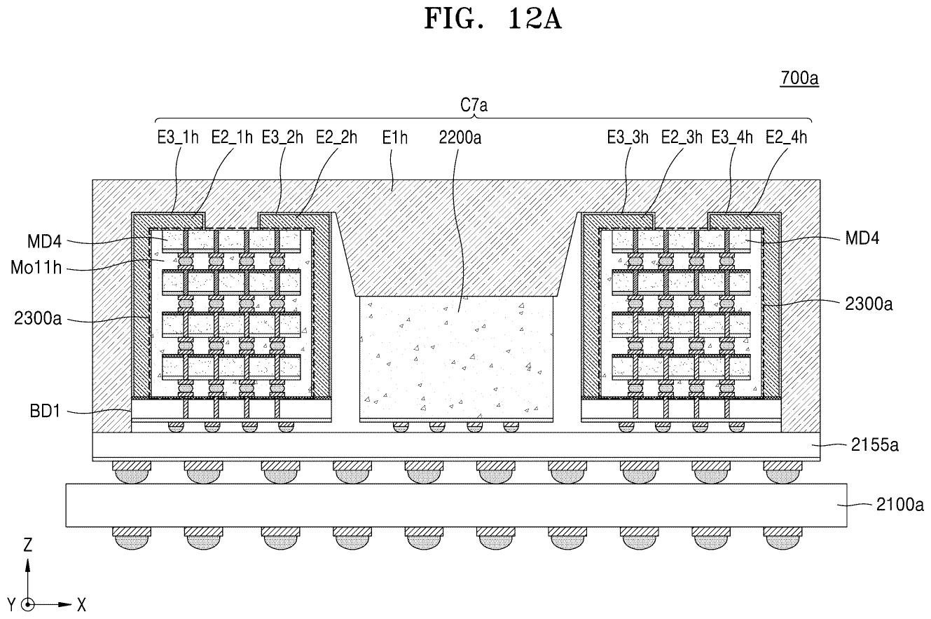

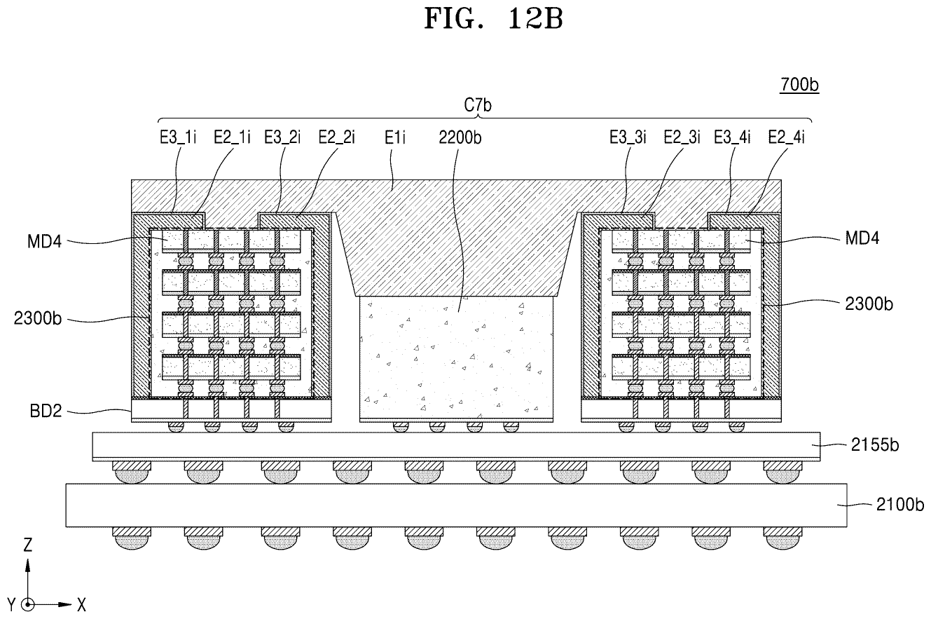

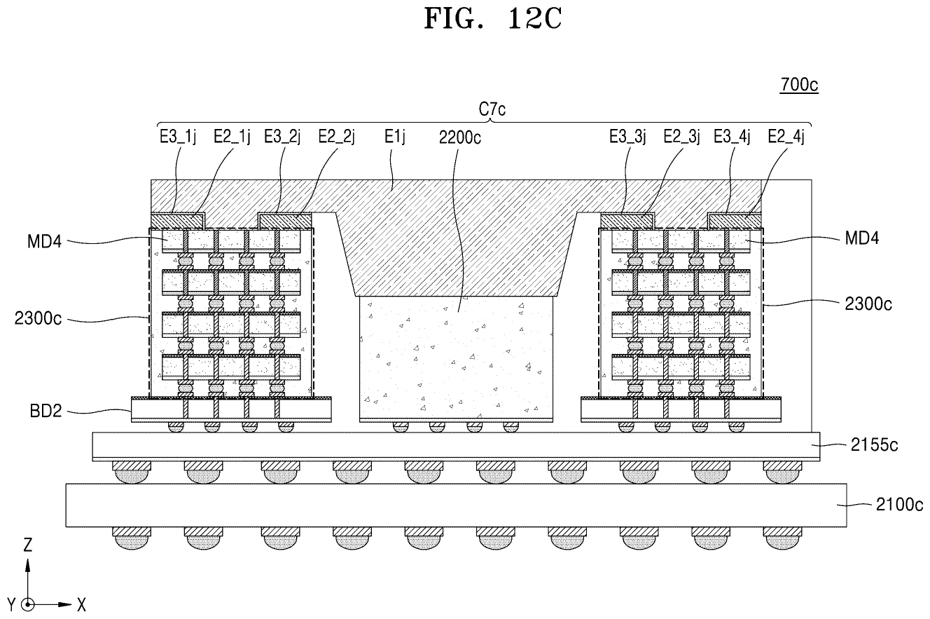

FIGS. 12A to 12C illustrate semiconductor devices each including a memory device and a capacitor, according to an example embodiment.

In describing FIGS. 12A to 12C, descriptions of structures that are substantially the same as those of the aforementioned capacitors and the memory devices are not repeated.

Referring to FIG. 12A, a semiconductor device 700a may include a package substrate 2100a, an interposer 2155a, a SoC 2200a, memory devices 2300a, and a capacitor C7a. According to an embodiment, a single SoC 2200a and two memory devices 2300a, each including a plurality of memory dies, may be arranged on the upper portion of the interposer 2155a, but embodiments are not limited thereto. A plurality of SoCs and at least three memory devices may be included. According to an embodiment, the capacitor C7a may include a first electrode E1h, second electrodes E2_1h, E2_2h, E2_3h, and E2_4h, and dielectrics E3_1h, E3_2h, E3_3h, and E3_4h. According to an embodiment, a single first electrode E1h may be provided, and the second electrodes E2_1h, E2_2h, E2_3h, and E2_4h, and the dielectrics E3_1h, E3_2h, E3_3h, and E3_4h may each be provided as four. The first electrode E1h may be arranged to cover both the memory device 2300a and the SoC 2200a. According to an embodiment, the first electrode E1h may contact the SoC 2200a. According to an embodiment, the first electrode E1h may also contact the memory device 2300a. According to an embodiment, the second electrodes E2_1h and E2_2h may be arranged on the memory device 2300a, and the second electrodes E2_3h and E2_4h may be arranged on the memory device 2300a.

Referring to the structure of the capacitor C7a of FIG. 12A, the second electrodes E2_1h, E2_2h, E2_3h, and E2_4h may be formed to cover a first molding layer Mo11h of the memory device 2300a, and the dielectrics E3_1h, E3_2h, E3_3h, and E3_4h may be arranged on the second electrodes E2_1h, E2_2h, E2_3h, and E2_4h. According to an embodiment, the interposer 2155a may contact the first electrode E1h.

Referring to the embodiment of FIG. 12A, the portion of the memory device 2300a on the interposer 2155a, where the first molding layer Mo11h is formed, may be covered by the second electrodes E2_1h, E2_2h, E2_3h, and E2_4h and the dielectrics E3_1h, E3_2h, E3_3h, and E3_4h, and the SoC 2200a and the portions of the memory device 2300a, which correspond to the side portions of the buffer die BD1 and the interposer 2155a, may be covered by the first electrode E1h. An uppermost memory die of the memory device 2300a according to an embodiment may include TSVs that may be electrically connected to the first electrode E1h and the second electrodes E2_1h, E2_2h, E2_3h, and E2_4h.

Referring to FIG. 12B, a semiconductor device 700b may include a package substrate 2100b, an interposer 2155b, a SoC 2200b, memory devices 2300b including a plurality of memory dies, and a capacitor C7b. In describing FIG. 12B, descriptions of structures that are substantially the same as those provided with reference to FIG. 12A are not repeated.

Referring to FIG. 12B, the capacitor C7b may include a first electrode E1i, second electrodes E2_1i, E2_2i, E2_3i, and E2_4i, and dielectrics E3_1i, E3_2i, E3_3i, and E3_4i. When the capacitor C7a of FIG. 12A is compared with the capacitor C7b of FIG. 12B, the first electrode E1i of the capacitor C7b of FIG. 12B may not contact the interposer 2155b. According to an embodiment, the first electrode E1i may be formed to cover upper portions of the memory device 2300b and the SoC 2200b on the interposer 2155b, but may not be formed to cover the side surfaces of the memory device 2300b.

Referring to FIG. 12C, a semiconductor device 700c may include a package substrate 2100c, an interposer 2155c, a SoC 2200c, memory devices 2300c including a plurality of memory dies, and a capacitor C7c. In describing FIG. 12C, descriptions of structures that are substantially the same as those provided with reference to FIG. 12A are not repeated.

According to an embodiment, the capacitor C7c may include a first electrode E1j, second electrodes E2_1j, E2_2j, E2_3j, and E2_4j, and dielectrics E3_1j, E3_2j, E3_3j, and E3_4j. When the capacitor C7a of FIG. 12A is compared with the capacitor C7c of FIG. 12C, the second electrodes E2_1j, E2_2j, E2_3j, and E2_4j and the dielectrics E3_1j, E3_2j, E3_3j, and E3_4j of the capacitor C7c of FIG. 12C may be formed only in the area covering the upper surface of the memory device 2300c and may not be formed in the area contacting the side surfaces of the memory device 2300c. There may be some similarities with the semiconductor device of FIG. 6.

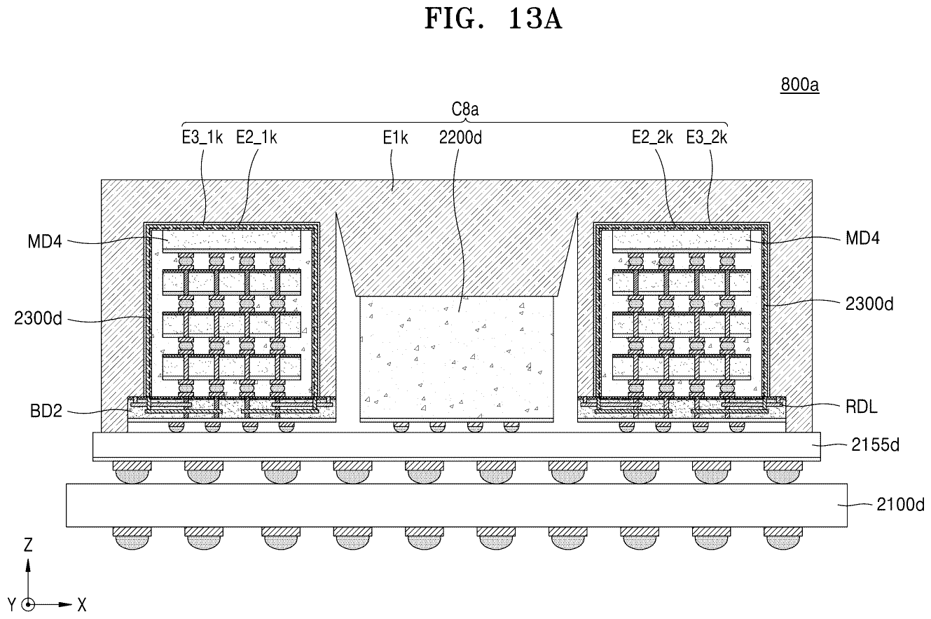

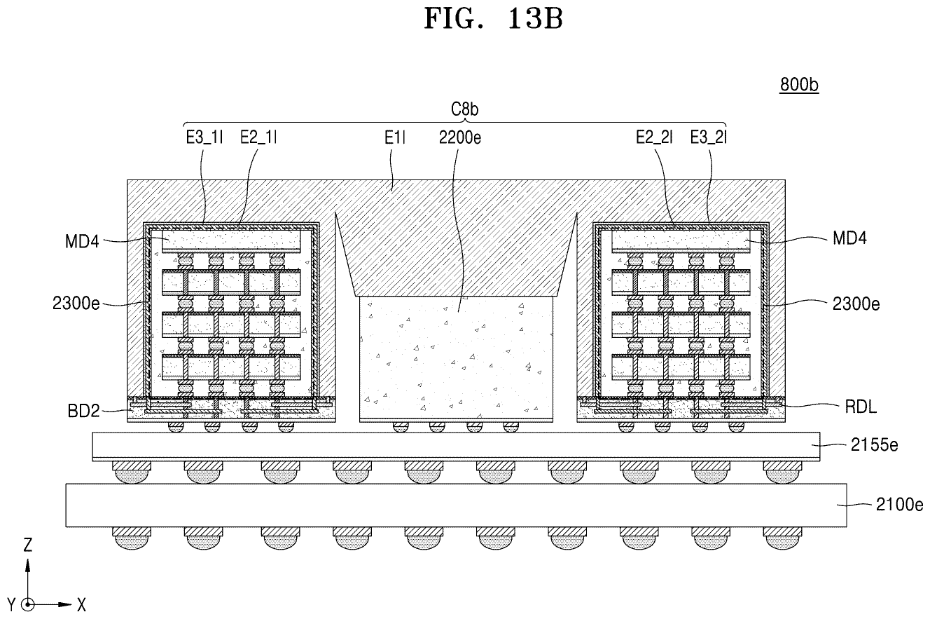

FIGS. 13A and 13B show semiconductor devices according to an example embodiment.

In describing FIGS. 13A and 13B, descriptions of structures that are substantially the same as those of the aforementioned capacitors and the memory devices are not repeated.

Referring to FIG. 13A, a semiconductor device 800a may include a package substrate 2100d, an interposer 2155d, a SoC 2200d, memory devices 2300d including a plurality of memory dies, and a capacitor C8a. According to an embodiment, the capacitor C8a may include a first electrode Elk, second electrodes E2_1k and E2_2k, and dielectrics E3_1k and E3_2k. According to an embodiment, the first electrode Elk may not contact the uppermost memory die MD4 of the memory device 2300d. According to an embodiment, the first electrode Elk may contact a buffer die BD2 of the memory device 2300d, the interposer 2155d, and the SoC 2200d. According to an embodiment, the uppermost memory die MD4 may not include TSVs, the buffer die BD2 may include an RDL, and the first electrode E1k may be electrically connected to the memory device 2300d through the RDL. The first electrode E1k of the capacitor C8a may contact the interposer 2155d. The connection structure between the capacitor C8a of FIG. 13A and the buffer die BD2 of the memory device 2300d may correspond to the connection structure between the capacitor C4 and the buffer die BD2 of FIG. 8.

Referring to FIG. 13B, a semiconductor device 800b may include a package substrate 2100e, an interposer 2155e, a SoC 2200e, memory devices 2300e including a plurality of memory dies, and a capacitor C8b. According to an embodiment, the capacitor C8b may include a first electrode E1l, second electrodes E2_1l and E2_2l, and dielectrics E3_1l and E3_2l. The difference between the capacitor C8b of FIG. 13B and the capacitor C8a of FIG. 13A lies in that the first electrode E1l of the capacitor C8b of FIG. 13B is not in contact with the interposer 2155e. According to an embodiment, the capacitor C8b may be formed within the range covering the memory device 2300e and the SoC 2200e, but may not contact the interposer 2155e.

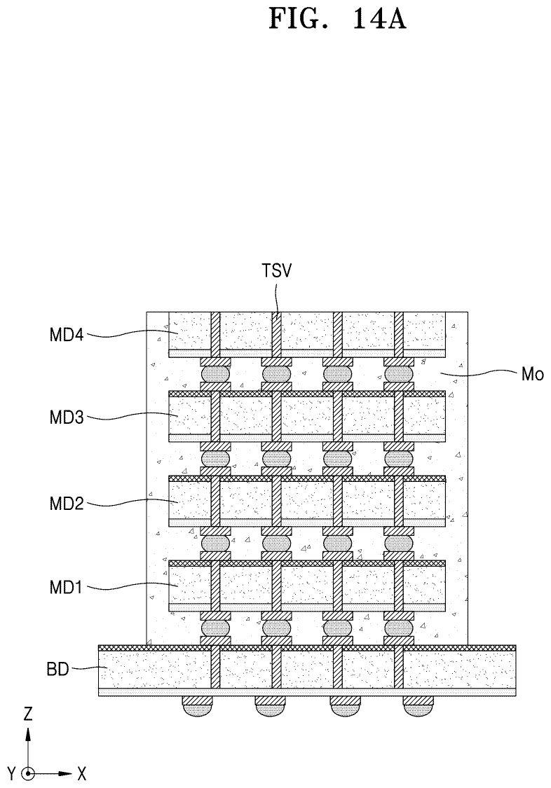

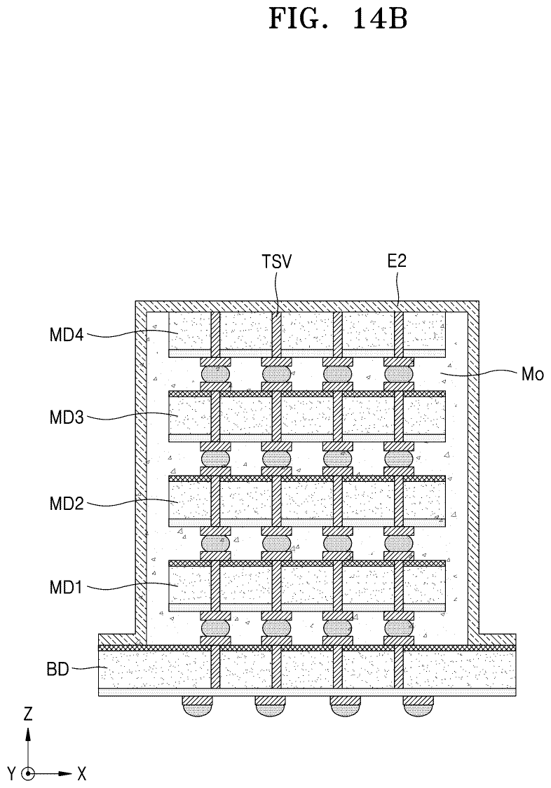

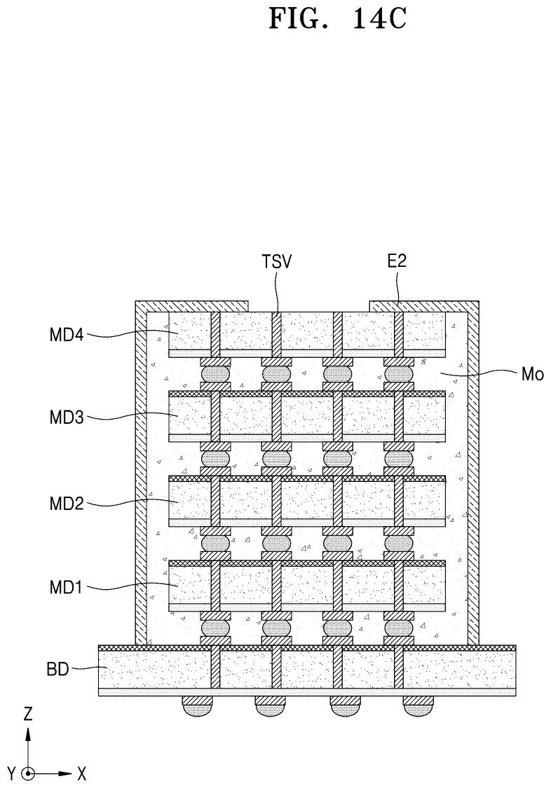

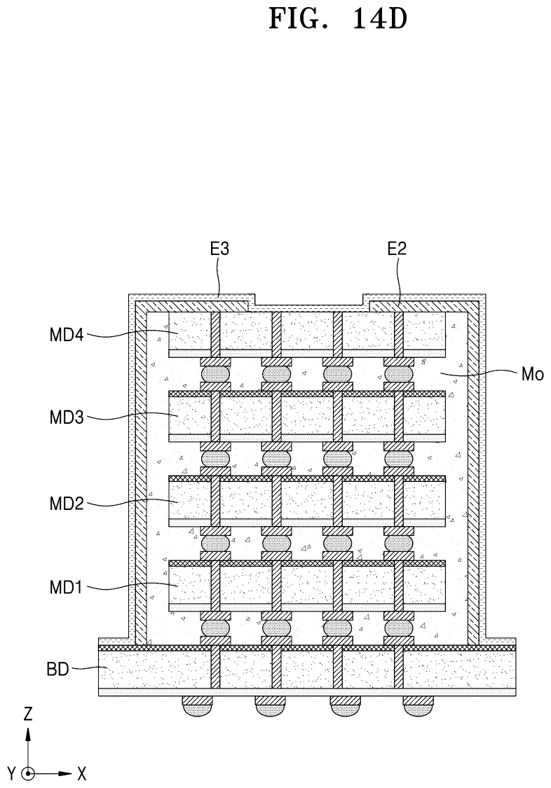

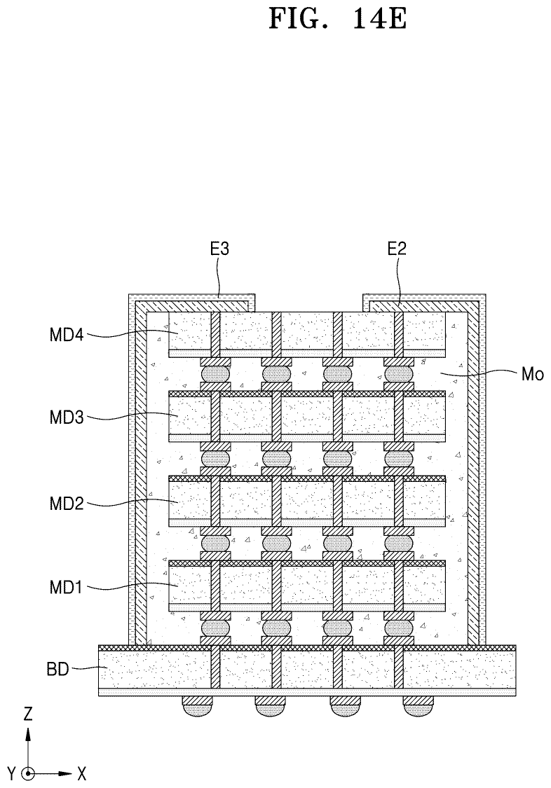

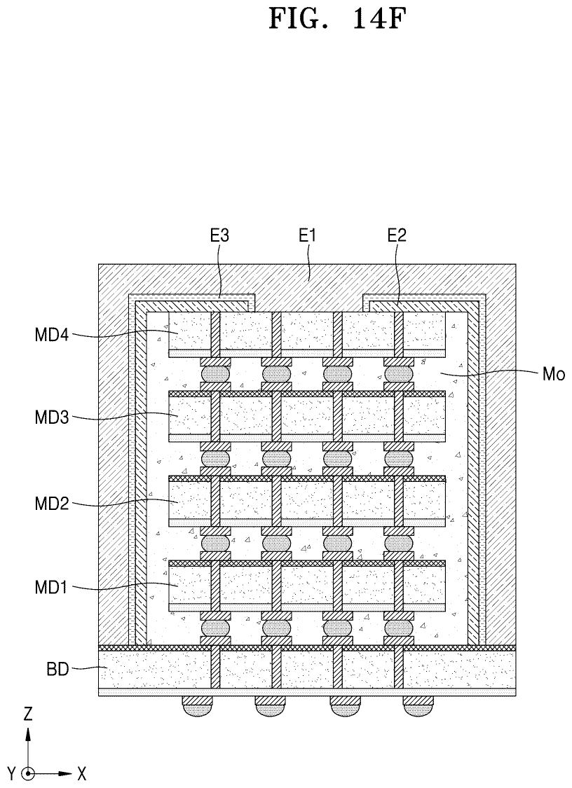

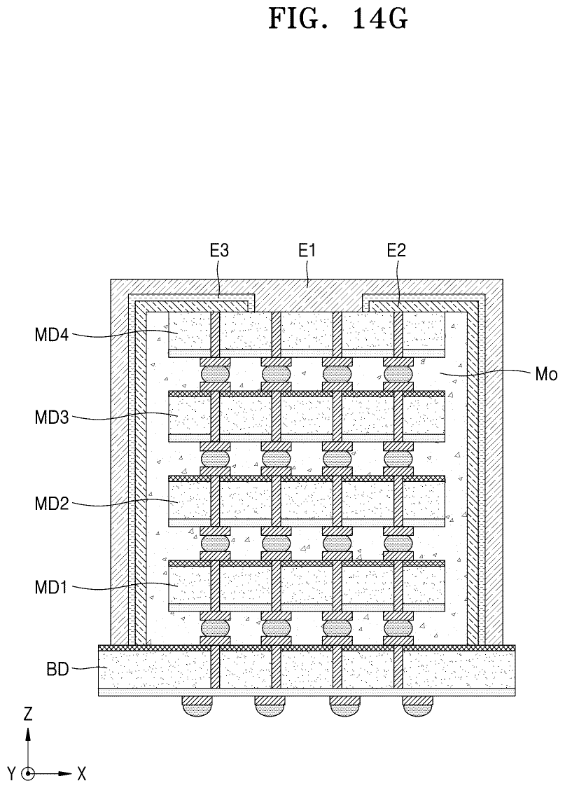

FIGS. 14A to 14G illustrate a method of manufacturing a semiconductor device according to an example embodiment.

FIG. 14A illustrates a buffer die BD and a plurality of memory dies MD1 to MD4 that are stacked on the buffer die BD. The buffer die BD and the memory dies MD1 to MD4 may include TSVs for establishing electrical connections therebetween. A first molding layer Mo that primarily protects the memory dies MD1 to MD4 may be formed to surround the memory dies MD1 to MD4. The first molding layer Mo may contact surfaces of the memory dies MD1 to MD4. Upper surfaces of the first molding layer Mo and an uppermost memory die MD4 may be coplanar.

Referring to FIG. 14B, a second electrode E2 may be deposited to entirely cover the first molding layer Mo and the uppermost memory die MD4. According to an embodiment, the second electrode E2 may be formed to fully cover the side portions of the first molding layer Mo and the upper surface of the uppermost memory die MD4. The second electrode E2 may contact upper and side surfaces of the first molding layer Mo and an upper surface of the buffer die BD.

Referring to FIG. 14C, a portion of the second electrode E2 may be etched to form a groove included in the first electrode. An etching target region may correspond to a portion of the area where the TSVs of the uppermost memory die MD4 are located. In addition, portions of the second electrode E2 on the buffer die BD may be removed by the etching process.

Referring to FIG. 14D, a dielectric E3 may be deposited. The dielectric E3 may be deposited on the upper portion of the second electrode E2. The dielectric E3 may contact upper and side surfaces of the second electrode E2. In addition, the dielectric E3 may be deposited on the buffer die BD and a portion of the upper surface of the uppermost memory die MD4.

Referring to FIG. 14E, a portion of the dielectric E3 may be etched to form the groove in the first electrode. The etching target region here may correspond to the region where the second electrode E2 is etched in FIG. 14C. Through this process, the dielectric E3 and the second electrode E2 may each be provided in plurality. In addition, portions of the dielectric E3 on the buffer die BD may be removed by the etching process.

Referring to FIG. 14F, the first electrode E1 may be deposited to cover the upper surface of the buffer die BD and the memory dies MD1 to MD4. The first electrode E1 may contact upper and side surfaces of the dielectric E3 and an upper surface of the buffer die BD.

Referring to FIG. 14G, the upper surface of the first electrode E1 may be ground to perform surface treatment. In the method illustrated in FIGS. 14A to 14G, the first electrode E1, the second electrodes E2, and the dielectrics E3 correspond to the first electrode E1, the second electrodes E2_1 and E2_2, and the dielectrics E3_1 and E3_2 of FIG. 5.

The method of manufacturing a semiconductor device illustrated in FIGS. 14A to 14G is provided to explain the method of manufacturing any one of the semiconductor devices according to the one or more embodiments in the present specification, and may also be applied to a method of manufacturing a semiconductor device having a different structure.

The semiconductor device, further comprising: a molding layer, wherein the molding layer contacts upper surfaces of the first electrode, the dielectric, and the second electrode.

The semiconductor device, wherein an upper surface of the molding layer is coplanar with an upper surface of an uppermost memory die among the plurality of memory dies.

The semiconductor device, wherein the capacitor comprises: at least two second electrodes; dielectrics on the at least two second electrodes; and a first electrode on the dielectrics, and wherein each of the second electrodes, the dielectrics, and the first electrode contact an upper surface of an uppermost memory die among the plurality of memory dies.

The semiconductor device, further comprising: a molding layer, wherein the molding layer contacts each of the at least two second electrodes, the dielectrics, and the first electrode.

The semiconductor device, wherein the first electrode includes a plurality of protrusions, and wherein at least one protrusion of the plurality of protrusions overlaps a region in which the first electrode contacts the upper surface of the uppermost memory die among the plurality of memory dies.

The semiconductor device, wherein the capacitor comprises: a second electrode; a dielectric on the second electrode; and a first electrode on the dielectric, and wherein the second electrode contacts at least one of the plurality of through silicon vias.

While the inventive concept has been particularly shown and described with reference to embodiments thereof, it will be understood that various changes in form and details may be made therein without departing from the spirit and scope of the following claims.

What is claimed is:

1. A semiconductor device comprising:
a buffer die configured to communicate with an external device;
a memory die stack including a plurality of memory dies stacked on the buffer die and connected to the buffer die through a plurality of through silicon vias; and
a capacitor arranged on an upper portion of an uppermost memory die among the plurality of memory dies,
wherein the capacitor surrounds at least some surfaces of the plurality of memory dies, when viewed in a top down view.

2. The semiconductor device of claim 1,
wherein the capacitor comprises:
a first electrode;
a second electrode; and
a dielectric arranged between the first electrode and the second electrode, and
wherein the first electrode and the second electrode are electrically connected to the memory die stack through the uppermost memory die.

3. The semiconductor device of claim 1,
wherein the capacitor comprises:
a first electrode;
a second electrode; and
a dielectric arranged between the first electrode and the second electrode, and
wherein the first electrode and the second electrode are electrically connected to the memory die stack through the buffer die.

4. The semiconductor device of claim 2,
wherein the uppermost memory die comprises through silicon vias, and
wherein the first electrode and the second electrode are electrically connected to the memory die stack through the through silicon vias of the uppermost memory die.

5. The semiconductor device of claim 3,
wherein the buffer die comprises a redistribution layer, and
wherein the first electrode and the second electrode are electrically connected to the memory die stack through the redistribution layer of the buffer die.

6. The semiconductor device of claim 1, wherein the capacitor comprises a decoupling capacitor or a power capacitor.

7. The semiconductor device of claim 1,
wherein the capacitor comprises:
at least two second electrodes;
dielectrics arranged on upper portions of the second electrodes; and
a first electrode arranged on upper portions of the dielectrics

8. The semiconductor device of claim 1,
wherein the capacitor comprises:
a first electrode;
a second electrode; and
a dielectric arranged between the first electrode and the second electrode, and
wherein one side surface of the first electrode comprises a protrusion structure,
wherein the protrusion structure includes a plurality of protrusions.

9. A semiconductor device comprising:
a memory device comprising a buffer die configured to communicate with an external device and a memory die stack including a plurality of memory dies stacked on the buffer die and connected to the buffer die through a plurality of through silicon vias; and
a capacitor electrically connected to the memory device and covering at least a portion of the memory device,
wherein the capacitor comprises:
a first electrode;
a second electrode; and
a dielectric arranged between the first electrode and the second electrode.

10. The semiconductor device of claim 9,
wherein the first electrode comprises a groove, and
wherein an uppermost memory die among the plurality of memory dies comprises a through silicon via configured to be connected to the groove.

11. The semiconductor device of claim 9,
wherein the buffer die comprises a redistribution layer, and
wherein the first electrode and the second electrode are electrically connected to the memory die stack through the redistribution layer of the buffer die.

12. The semiconductor device of claim 11, wherein the uppermost memory die among the plurality of memory dies does not comprise a through silicon via.

13. The semiconductor device of claim 9,
wherein one side surface of the first electrode comprises a protrusion structure, and
wherein the protrusion structure includes a plurality of protrusions.

14. The semiconductor device of claim 9, wherein, with respect to a vertical cross section, a cross-sectional area of the first electrode is a same as or greater than a cross-sectional area of the uppermost memory die among the plurality of memory dies.

15. The semiconductor device of claim 9, wherein the first electrode, the dielectric, and the second electrode each contact an upper surface of the buffer die.

16. The semiconductor device of claim 9, wherein the capacitor comprises a decoupling capacitor or a power capacitor.

17. The semiconductor device of claim 9, wherein thicknesses of the first electrode and the second electrode are greater than a thickness of the dielectric.

18. A semiconductor device comprising:
a memory device comprising a buffer die configured to communicate with an external device and a memory die stack including a plurality of memory dies stacked on the buffer die and connected to the buffer die through a plurality of through silicon vias;
a system on chip including a processor;
an interposer substrate connecting the memory device to the system on chip; and
a capacitor electrically connected to the memory device and covering at least a portion of each of the memory device and the system on chip.

19. The semiconductor device of claim 18,
wherein an uppermost memory die among the plurality of memory dies comprises a through silicon via,
wherein the capacitor includes a first electrode, a dielectric, and a second electrode, and
wherein the first electrode and the second electrode are electrically connected to the memory die stack through the through silicon via of the uppermost memory die.

20. The semiconductor device of claim 18,
wherein the buffer die comprises a redistribution layer,
wherein the capacitor includes a first electrode, a dielectric, and a second electrode, and
wherein the first electrode and the second electrode are electrically connected to the memory die stack through the redistribution layer of the buffer die.
